(19) United States
(12) Patent Application Publication
(10) Pub. No.: US 2018/0100891 A1
(43) Pub. Date: Apr. 12, 2018

(54) INTEGRATED CIRCUIT TEMPERATURE DETERMINATION USING PHOTON EMISSION DETECTION

(71) Applicant: INTERNATIONAL BUSINESS MACHINES CORPORATION, Armonk, NY (US)

(72) Inventors: Franco Stellari, Waldwick, NJ (US); Alan J. Weger, Mohegan Lake, NY (US)

(73) Assignee: INTERNATIONAL BUSINESS MACHINES CORPORATION, ARMONK, NY (US)

(21) Appl. No.: 15/289,307

(22) Filed: Oct. 10, 2016

(51) Int. Cl. G01R 31/28; G01J 5/00; G01R 31/303

(52) U.S. Cl. CPC G01R 31/2874; G01J 2005/0077; G01R 31/303; G01J 5/0096

(57) ABSTRACT

A computer-implemented method includes receiving a plurality of images from a device under test (DUT), whereby each of the plurality of images is generated by operating the DUT at different frequency conditions. The computer-implemented method further includes receiving emission intensity values from a corresponding pixel location on each of the received plurality of images, receiving an electrical leakage current parameter for the DUT that corresponds to a change in leakage current based on a change in temperature, and receiving a temperature parameter for the DUT that corresponds to an ambient temperature value at which the DUT is maintained. A temperature value at the corresponding pixel location is then determined based on the different frequency conditions, the emission intensity values associated with the different frequency conditions, the electrical leakage current parameter, and the ambient temperature value.

### BACKGROUND

The present invention generally relates to detecting photon emissions, and more particularly, to determining temperature measurements on an integrated circuit based on the detected photon emissions.

Performing temperature measurements on integrated circuit (IC) devices, among other things, determines various operational characteristics about such devices. For example, leakage current for a transistor device within an IC may double for a detected temperature rise of about 30-40 degrees Celsius.

### SUMMARY

According to one or more embodiments, photon emissions from different components (e.g., transistors) of an integrated circuit may be detected and utilized in order to establish temperature-measurement values at the component level of the integrated circuit.

According to one embodiment, a computer-implemented method includes receiving a plurality of images from a device under test (DUT), whereby each of the plurality of images is generated by operating the DUT at a different frequency condition. The computer-implemented method further includes receiving emission intensity values from a corresponding pixel location on each of the received plurality of images, receiving an electrical leakage current parameter for the DUT that corresponds to a change in leakage current based on a change in temperature, and receiving a temperature parameter for the DUT that corresponds to an ambient temperature value at which the DUT is maintained. A temperature value at the corresponding pixel location is then determined based on the different frequency conditions, the emission intensity values associated with the different frequency conditions, the electrical leakage current parameter, and the ambient temperature value.

According to another exemplary embodiment, a computer program product includes one or more non-transitory computer-readable storage devices and program instructions stored on at least one of the one or more non-transitory storage devices. The program instructions are executable by a processor, whereby the program instructions include: instructions to receive a plurality of images from a device under test (DUT), whereby each of the plurality of images is generated by operating the DUT at a different frequency condition; instructions to receive emission intensity values from a corresponding pixel location on each of the received plurality of images; instructions to receive, for the DUT, an electrical leakage current parameter corresponding to a change in leakage current based on a change in temperature; instructions to receive, for the DUT, a temperature parameter corresponding to an ambient temperature value at which the DUT is maintained; and instructions to determine a temperature value at the corresponding pixel location based on the different frequency conditions, the emission intensity values associated with the different frequency conditions, the electrical leakage current parameter, and the ambient temperature value.

According to yet another exemplary embodiment, a computer system includes one or more processors, one or more computer-readable memories, one or more non-transitory computer-readable storage devices, and program instructions stored on at least one of the one or more non-transitory storage devices for execution by at least one of the one or more processors via at least one of the one or more memories. The computer system is capable of performing a method that includes receiving a plurality of images from a device under test (DUT), whereby each of the plurality of images is generated by operating the DUT at a different frequency condition; receiving emission intensity values from a corresponding pixel location on each of the received plurality of images; receiving, for the DUT, an electrical leakage current parameter corresponding to a change in leakage current based on a change in temperature; receiving, for the DUT, a temperature parameter corresponding to an ambient temperature value at which the DUT is maintained; and determining a temperature value at the corresponding pixel location based on the different frequency conditions, the emission intensity values associated with the different frequency conditions, the electrical leakage current parameter, and the ambient temperature value.

### BRIEF DESCRIPTION OF THE SEVERAL VIEWS OF THE DRAWINGS

FIG. 1 shows a block diagram of an exemplary system for determining temperature values of an integrated circuit (IC) device under test (DUT) based on photon emission detection, according to one embodiment;

FIGS. 2A-2C show an exemplary flowchart of a process used to determine the temperature values of the IC device under test (DUT) based on photon emission detection, according to one embodiment;

FIG. 3 is a block diagram of hardware and software for executing the process flows of FIGS. 2A-2C, according to one embodiment; and

FIG. 4 shows example temperature maps generated by the process of FIGS. 2A-2C, according to one embodiment.

The drawings are not necessarily to scale. The drawings are merely schematic representations, not intended to portray specific parameters of the invention. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the presented embodiments.

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The one or more exemplary embodiments described herein are directed to, among other things, determining temperature values for different areas of an IC device under test (i.e., a DUT) by capturing and processing images taken from the device. Emission intensities at each pixel location on the images are measured during image capture, whereby the emission intensities include values that are proportional to photon emissions generated by the DUT at each pixel location. A photon emission model is then utilized to determine temperature values corresponding to each pixel location associated with the DUT. Moreover, the photon emission model may determine whether the photon emissions are a result of component (e.g., NFET/PFET transistors) leakage current or switching operations. The high spatial resolution of the determined temperature values, and additionally the photon emission dependence (i.e., leakage current vs. switching operations), may be applied to a myriad of applications such as, but not limited to, on-chip temperature sensor calibrations, generating changes in operating conditions of the DUT, and identifying and correcting semiconductor process variations between different fabricated DUTs. Generally, the foregoing mentioned exemplary applications of the disclosed embodiments provide, among other things, various improvements to the field of IC testing, evaluation, calibration, and process control.

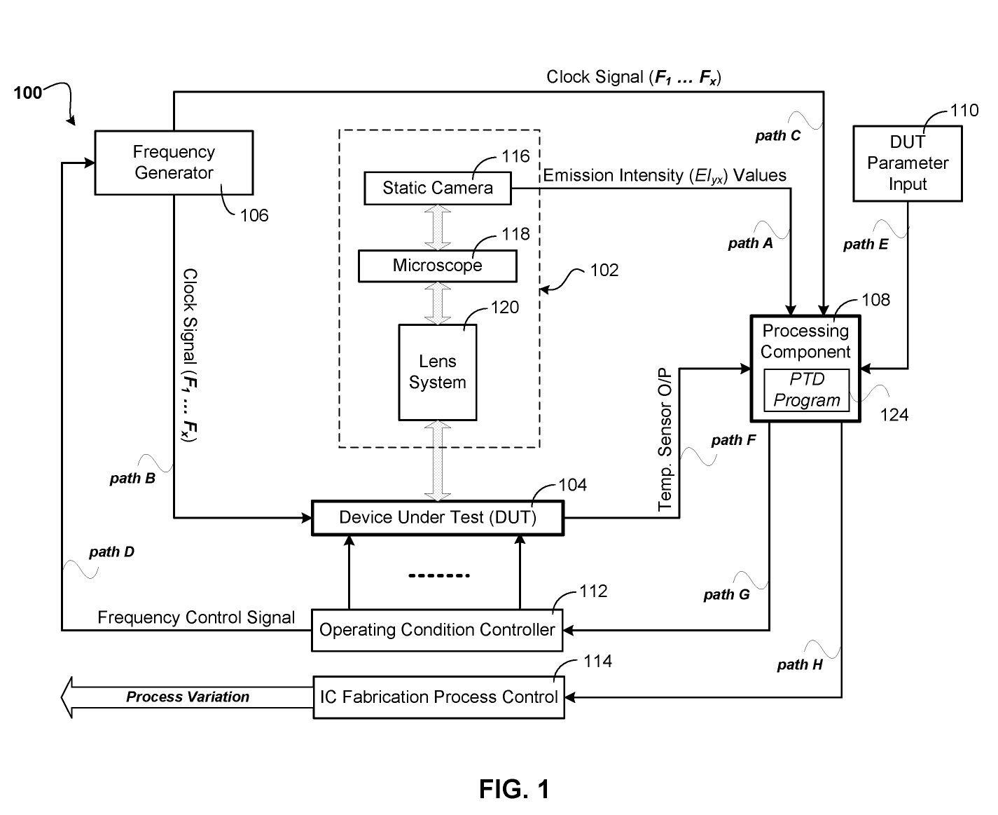

FIG. 1 is a block diagram of an exemplary system 100 for determining temperature values of an integrated circuit (IC) device under test (DUT) based on photon emission detection, according to one embodiment. The exemplary system 100 may include a microscope apparatus 102, a device under test (DUT) 104, a frequency generator 106, a processing component 108, a DUT parameter input component 110, an operating condition controller 112, and an IC fabrication process control unit 114.

As depicted, the microscope apparatus 102 may include a static camera device 116, a microscope body 118, and a lens system 120. The lens system 120 optically receives images from the DUT 104 device and transfers these images via the microscope body 118 to the static camera device 116 coupled to the microscope body 118. The static camera's 116 sensor and corresponding electrical circuitry (not shown) convert received photons to electrical current. Accordingly, at static camera device 116, photons emitted from the DUT 104 are received and converted to a corresponding electrical current based on the emission intensity of the generated photons from the DUT 104. For example, the emission intensity from the DUT 104 at each pixel location of the camera sensor can be represented as a digital output value that is proportional to the received photon count. The digital output values from the camera sensor that correspond to the emission intensities from the DUT 104 at the pixel locations are then coupled (path A) to the processing component 108. In general, any suitable image sensor device such as static camera device 116 may be utilized to capture images (i.e., taken from a plan view perspective) of the DUT 104. Example image sensor devices may include an Indium Gallium Arsenide (InGaAs) camera, a charge coupled device (CCD), or a Mercury Cadmium Telluride (MCT) Camera.

Frequency generator 106 includes any signal generation instrument capable of applying (path B) different user-determinable frequencies (e.g., F₁ . . . Fₓ) from its output to the DUT 104. Information (e.g., frequency value: F₁) associated with the generated frequencies (e.g., F₁ . . . Fₓ) is also output from the generator 106 and sent (path C) to the processing component 108. The frequency generator 106 may also include a control input for facilitating being controlled by another external device. For example, a frequency control signal generated from the operating condition controller 112 may be sent (path D) to the frequency generator 106 input in order to set or vary the frequency setting of the signal output from the generator 106 along path B.

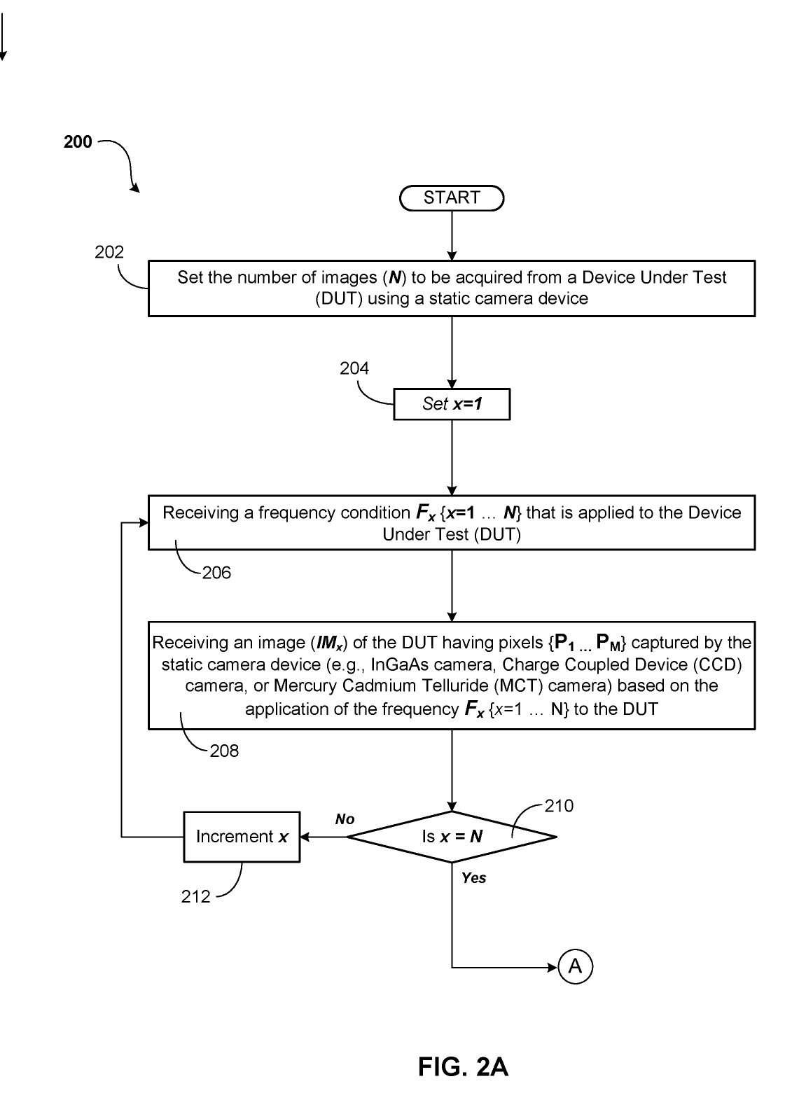

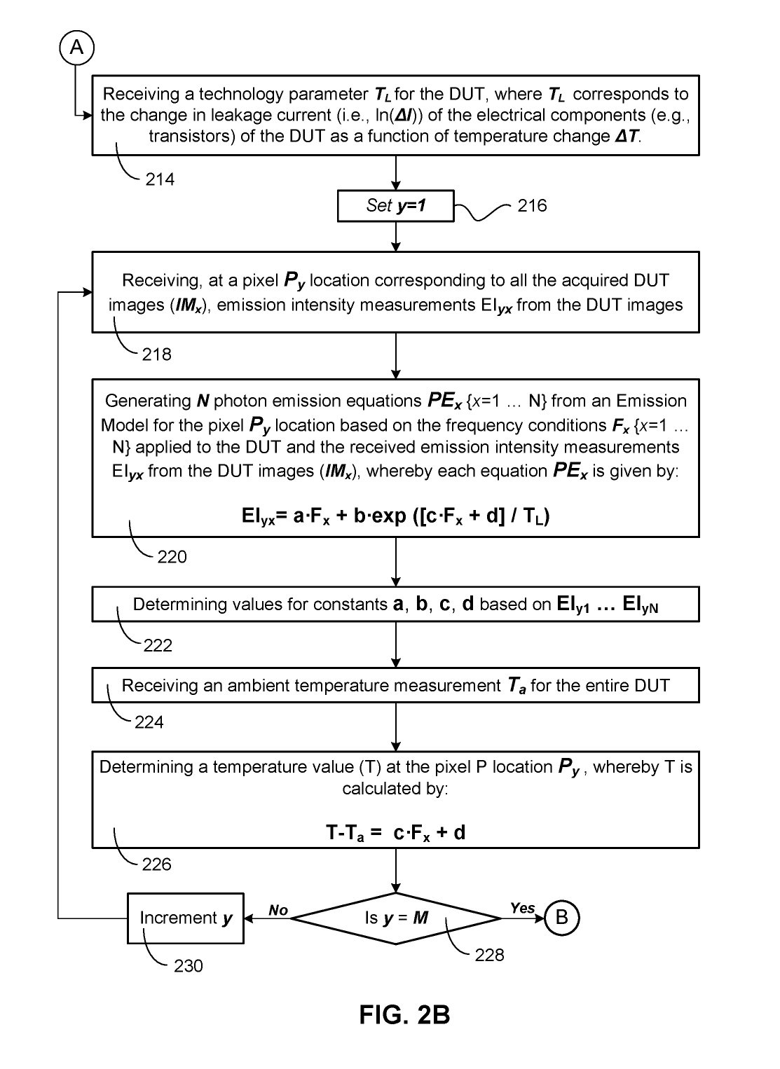

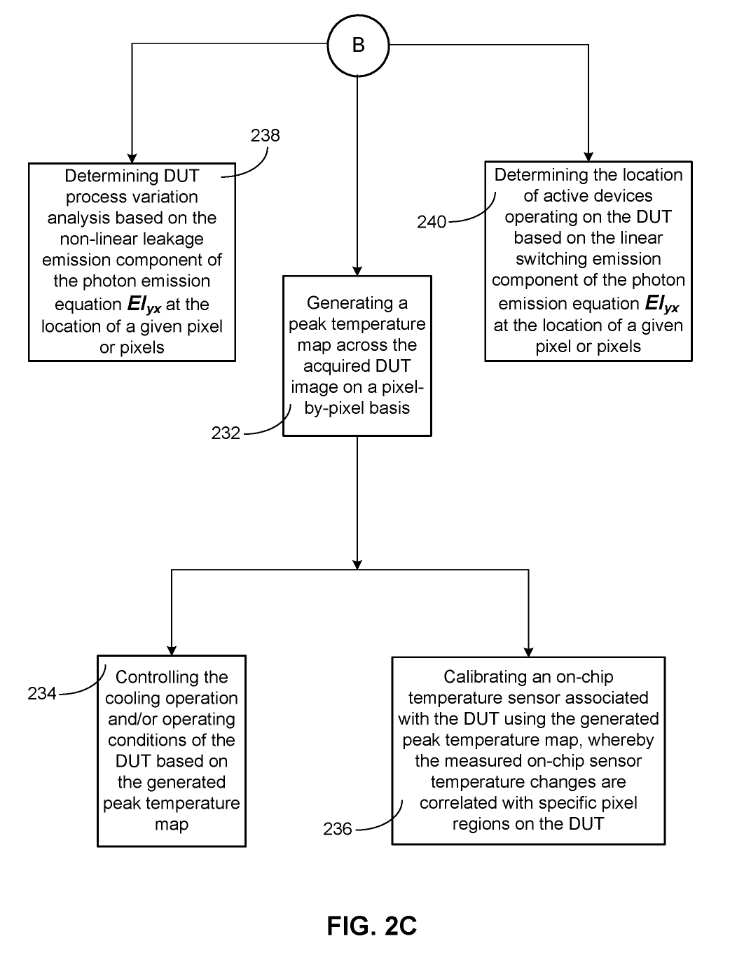

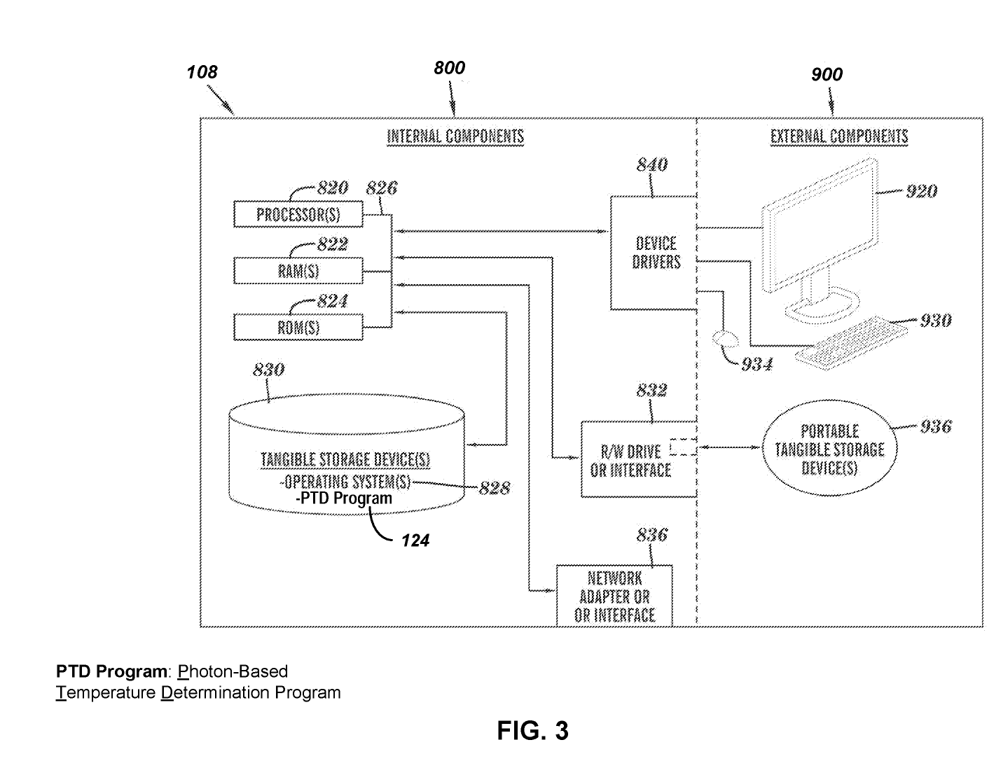

Processing component 108 may include hardware, software, or any combination thereof that is capable of processing multiple inputs for facilitating the control and/or evaluation of different conditions associated with the DUT 104. According to one non-limiting example, processing component 108 may include a device or system similar to, or the same as, that depicted and described in relation to FIG. 3. Moreover, details of the processing carried out by component 108 is found in relation to the flowcharts depicted in FIGS. 2A-2C.

As further illustrated in FIG. 1, the processing component 108 may receive (path A) emission intensity values (EI_{yx}) associated with the captured images of the DUT by the camera device 116 coupled to the microscope body 118. Processing component 108 may further receive (path C) clock frequency settings or conditions (F₁ . . . Fₓ) that are applied to the DUT during image capture. Various parameters associated with the DUT are also provided (path E) to the processing component 108 by the DUT parameter input component 110. Non-limiting examples of such parameters include a measured ambient temperature Tₐ of the DUT 104 (i.e., temperature of the cooled DUT device) and a technology parameter T_{L} (i.e., a temperature based leakage current value) of the DUT 104. The processing and application of these received inputs by the processing component 108 is described in detail in the following paragraphs, in particular, the flowcharts of FIGS. 2A-2C.

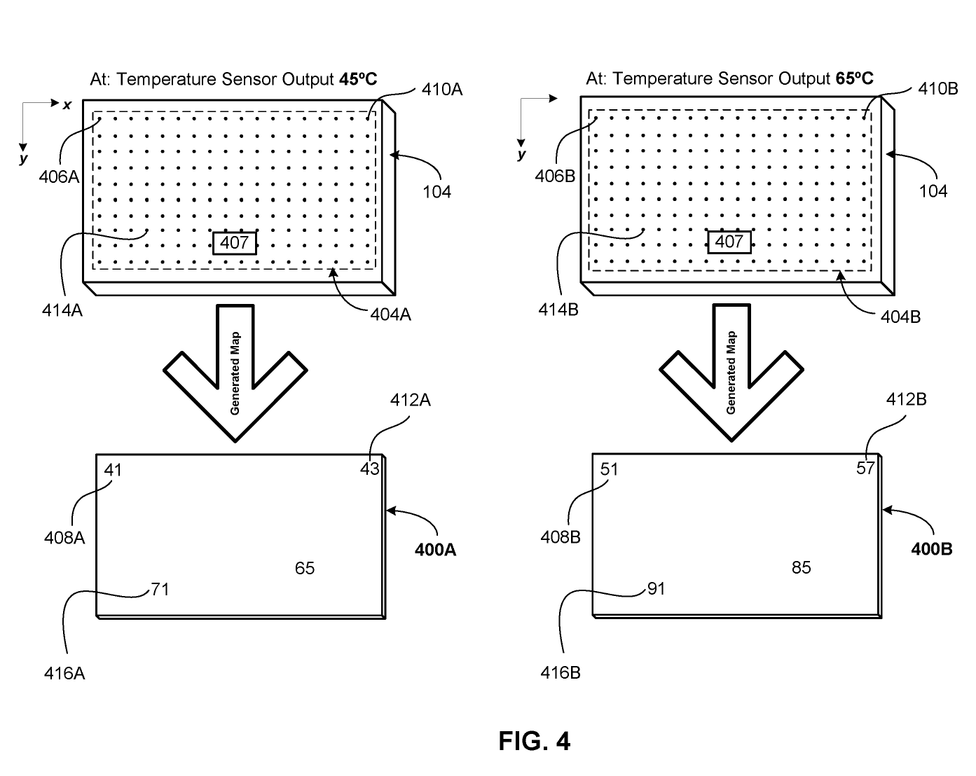

Processing component 108 may facilitate different changes to the state of the DUT 104 or the fabrication process of the DUT 104 in response to processing the received inputs along paths A, C, and E. Further, the processing component 108 may receive values from an on-chip temperature sensor (path F) within the DUT 104. Based on the processing component 108 generating a temperature map of the DUT 104 on a pixel-by-pixel basis, the temperature sensor can then be calibrated to correlate its output values to different temperature maps. Thus, for each on-chip temperature sensor output value, the actual temperature at each location of the DUT is known. FIG. 4, described below, provides an example of a temperature map that can be generated by one or more of the outputs (path G, path H) from processing component 108.

Referring to FIG. 4, example temperature maps 400A, 400B of the DUT 104 are shown, whereby at each of the pixel locations 404A, 404B of the captured images of the DUT 104, a specific temperature measurement is determined based on the photon emissions from the DUT 104. For example, for an on-chip temperature sensor output of 45° C., at pixel location 406A, the corresponding generated temperature map 400A illustrates a determined temperature value of 41° C., as indicated at 408A. Similarly, for the on-chip temperature sensor output of 45° C., at pixel location 410A, the corresponding generated temperature map 400A illustrates a determined temperature value of 43° C., as indicated at 412A. According to another example, for the on-chip temperature sensor output of 45° C., at pixel location 414A, the corresponding generated temperature map 400A illustrates a determined temperature value of 71° C., as indicated at 416A. For illustrative brevity only four temperature values are shown on temperature map 400A. However, it will be appreciated that the temperature map contemplates a determined temperature value for each of the corresponding pixel locations 404A associated with the captured image.

For example, for an alternative on-chip temperature sensor output of 65° C., at pixel location 406B, the corresponding generated temperature map 400B illustrates a determined temperature value of 51° C., as indicated at 408B. Similarly, for the on-chip temperature sensor output of 65° C., at pixel location 410B, the corresponding generated temperature map 400B illustrates a determined temperature value of 57° C., as indicated at 412B. According to another example, for the on-chip temperature sensor output of 65° C., at pixel location 414B, the corresponding generated temperature map 400B illustrates a determined temperature value of 91° C., as indicated at 416B. For illustrative brevity only four temperature values are shown on temperature map 400B. However, it will be appreciated that the temperature map contemplates a determined temperature value for each of the corresponding pixel locations 404B associated with the captured image.

Referring back to FIG. 1, one output (path G) of the processing component 108 may be used to control the operating conditions of the DUT 104 via the operating condition controller 112. For example, based on a generated temperature map, the processing component 108 may determine that a particular region of the chip is running at a temperature that exceeds a safe operating temperature for the DUT 104. Responsive to this determination, the processing component 108 may then send a control signal to the operating condition controller 112 to vary one or more operating parameters of the DUT 104. These one or more operating parameters may include, without limitation, the supply voltage applied to the DUT 104, the clock frequency applied to the DUT 104, and/or the amount of cooling (i.e., air or coolant) applied to the DUT 104.

Another output (path H) of the processing component 108 may be used to assess the fabrication process of other identical or similar DUT devices via an IC fabrication process control unit 114. The processing component 108 can determine variations in temperature measurement values between the same regions/devices of identical fabricated DUT devices. The processing component 108 may further indicate variations in the measured non-linear leakage emissions associated with the same regions/devices of identical fabricated DUT devices. Also, the processing component 108 may further indicate variations in the measured linear switching emissions associated with the same regions/devices of identical fabricated DUT devices. These variations may be utilized by the IC fabrication process control unit 114 to facilitate any fabrication process changes in order to reduce the process variations occurring during the manufacture of the identical DUTs. Identical DUTs mean devices (e.g., chips) that are manufactured on the same wafer or different wafers using the same device fabrication process, whereby each die on the wafer contains a copy of the same circuit (e.g., each chip has the same circuit design).

The DUT 104 and microscope apparatus 102 are enclosed in a controlled environment in order to isolate the detection of photon emissions by the camera 116 to those generated by the DUT 104 during operation. For example, a controlled environment can include, without limitation, a dark enclosure in which the DUT 104 and microscope 102 are located, an electrically isolated enclosure for avoiding/mitigating electromagnetic or electrical interferences with the DUT 104 from external sources, anti-vibration means for the enclosure, temperature control of the enclosure, etc.

FIGS. 2A-2C show an exemplary flowchart of a process 200 used to determine the temperature values of the IC device under test (DUT) based on photon emission detection, according to one embodiment. As illustrated in FIG. 1, the process of FIGS. 2A-2C may be implemented as a photon-based temperature determination (PTD) program running on processing component 108. FIGS. 2A-2C are described with the aid of FIG. 1.

Referring to FIG. 2A, at 202, the number of images (N) to be acquired or captured by the camera device 116 from the DUT 104 is determined. As described in the following paragraphs, the photon emission model corresponds to determining the value of four (4) unknown constants, and thus, solving at least four (4) photon emission equations. Therefore, in order to generate these four equations, four images (i.e., N=4) of the DUT 104 are to be captured and processed such that each image is used to generate each equation. At 204, variable “x” is set to an initial start value of ‘1’.

At 206, a frequency value F₁ (Fₓ where x=1) that is applied to the DUT 104 is received. For example, a clock frequency F₁ of 600 MHz is applied to the DUT 104. At 208, based on the application of frequency F₁ (Fₓ where x=1) to the DUT 104, a captured image IM₁ (IMₓ where x=1) of the DUT 104 having pixels P₁ to P_{M} is received from the static camera device 116. The static camera may include an InGaAs camera, a Charge Coupled Device (CCD) camera, or a Mercury Cadmium Telluride (MCT) camera. The received image IM₁ includes the digital output values from pixels P₁ to P_{M}, which are stored for processing. As previously described, these digital output values correspond to the emission intensities detected by the pixels (P₁ to P_{M}) and are thus representative of the detected photon emissions from the DUT 104.

At 210, the value of x is compared to the set value of the number of images N to be acquired. In the current example, N is set to four (4), which is indicative of capturing four (4) images of the DUT 104. Since x is currently set to ‘1’ and N=4, x is not equal to N. Thus, at 212, x is incremented, whereby x=2. The process then returns back from 212 to 206.

Once image IM₁ (IMₓ where x=1) is acquired from the DUT 104 by the camera 116 and x is further determined to be less than N at 210, another frequency value F₂ (Fₓ where x=2) is applied to the DUT 104.

At 206, the frequency value F₂ (Fₓ where x=2) that is applied to the DUT 104 is received. For example, a clock frequency F₂ of 1200 MHz is applied to the DUT 104. At 208, based on the application of frequency F₂ (Fₓ where x=2) to the DUT 104, a captured image IM₂ (IMₓ where x=2) of the DUT 104 having pixels P₁ to P_{M} is received from the static camera device 116. The received image IM₂ includes the digital output values from pixels P₁ to P_{M}, which are also stored for processing. As previously described, these digital output values correspond to the emission intensities detected by the pixels (P₁ to P_{M}) and are thus representative of the detected photon emissions from the DUT 104 under the new operating condition F₂.

At 210, the value of x is compared to the set value of the number of images N to be acquired. Since x is currently set to ‘2’ and N=4, x is still not equal to N. Thus, at 212, x is incremented, whereby x=3. The process then returns back from 212 to 206.

Once image IM₂ (IMₓ where x=2) is acquired from the DUT 104 by the camera 116 and x is further determined to be less than N at 210, another frequency value F₃ (Fₓ where x=3) is applied to the DUT 104.

At 206, the frequency value F₃ (Fₓ where x=3) that is applied to the DUT 104 is received. For example, a clock frequency F₃ of 2400 MHz is applied to the DUT 104. At 208, based on the application of frequency F₃ (Fₓ where x=3) to the DUT 104, a captured image IM₃ (IMₓ where x=3) of the DUT 104 having pixels P₁ to P_{M} is received from the static camera device 116. The received image IM₃ includes the digital output values from pixels P₁ to P_{M}, which are also stored for processing. As previously described, these digital output values correspond to the emission intensities detected by the pixels (P₁ to P_{M}) and are thus representative of the detected photon emissions from the DUT 104 under the new operating condition F₃.

At 210, the value of x is compared to the set value of the number of images N to be acquired. Since x is currently set to ‘3’ and N=4, x is still not equal to N. Thus, at 212, x is incremented, whereby x=4. The process then returns back from 212 to 206.

Once image IM₃ (IMₓ where x=3) is acquired from the DUT 104 by the camera 116 and x is further determined to be less than N at 210, another frequency value F₄ (Fₓ where x=4) is applied to the DUT 104.

At 206, the frequency value F₄ (Fₓ where x=4) that is applied to the DUT 104 is received. For example, a clock frequency F₄ of 3400 MHz is applied to the DUT 104. At 208, based on the application of frequency F₄ (Fₓ where x=4) to the DUT 104, a captured image IM₄ (IMₓ where x=4) of the DUT 104 having pixels P₁ to P_{M} is received from the static camera device 116. Received image IM₄ includes the digital output values from pixels P₁ to P_{M}, which are also stored for processing. As previously described, these digital output values correspond to the emission intensities detected by the pixels (P₁ to P_{M}) and are thus representative of the detected photon emissions from the DUT 104 under the new operating condition F₄.

At 210, the value of x is compared to the set value of the number of images N to be acquired. Since x is currently set to ‘4’ and N=4, x is now equal to N and the image capture phase terminates as the process moves to 214 (FIG. 2B). As described in the following paragraphs, the captured images IM₁-IM₄ and their corresponding stored pixel emission intensities are utilized to determine location-specific temperature measurements at each pixel.

Referring now to FIG. 2B, using the acquired images IM₁-IM₄ (FIG. 2A) and other acquired parameters, a photon emission model facilitates the location-specific temperature measurements at each pixel according to one embodiment. At 214, a technology parameter T_{L} corresponding to the DUT 104 is received, whereby T_{L} corresponds to the change in leakage current (i.e., In (ΔI)) of the electrical components (e.g., transistors) of the DUT 104 as a function of temperature change ΔT. Thus, T_{L} represents how rapidly the leakage current increases with temperature. For example, if leakage current doubles for each 30° C., then T_{L}=30/ln (2)=43. The technology parameter T_{L} may be received from the DUT parameter input component 110, which can store and/or access different T_{L} values for different DUT devices. At 216, y is set to an initial value of ‘1’.

At 218, for a pixel P_{y} (P₁, where y=1) location corresponding to all the acquired DUT images (IMₓ), emission intensity measurements EI_{yx} from the DUT images are received. For example, for pixel P₁ corresponding to acquired image IM₁, emission intensity measurement EI₁₁ is received. For pixel P₁ corresponding to acquired image IM₂, emission intensity measurement EI₁₂ is received. For pixel P₁ corresponding to acquired image IM₃, emission intensity measurement EI₁₃ is received. For pixel P₁ corresponding to acquired image IM₄, emission intensity measurement EI₁₄ is received. Therefore, the emission intensity measurements for the same pixel (P₁) location on all the acquired images (IM₁-IM₄) are received for processing.

At 220, N photon emission equations PEₓ (x=1 . . . N) are generated from an Emission Model for the pixel P₁ (P_{y} where y=1) location based on the frequency conditions Fₓ (x=1 . . . N) applied to the DUT and the received emission intensity measurements EI_{yx} from the DUT images (IMₓ). Each equation PEₓ is given by:

EI_{yx}=a·Fₓ+b·e^{[(c·F}^{ₓ}^{+d)]/T}^{_{L}} Equation 1

Since N is set to four (4), four (4) photon emission equations PE₁-PE₄ are generated, whereby:

EI₁₁=a·F₁+b·e^{[(c·F}^{₁}^{+d)]/T}^{_{L}} Equation 2

EI₁₂=a·F₂+b·e^{[(c·F}^{₂}^{+d)]/T}^{_{L}} Equation 3

EI₁₃=a·F₃+b·e^{[(c·F}^{₃}^{+d)]/T}^{_{L}} Equation 4

EI₁₄=a·F₄+b·e^{[(c·F}^{₄}^{+d)]/T}^{_{L}} Equation 5

Equations 2-5 above are photon emission equations for a single pixel position based on the DUT 104 being operated at different clock frequency conditions (F₁-F₄).

At 222, equations 2-5 are solved for determining the values of unknown constants a, b, c, and d. Constants a-d may be bound to be either positive or negative in value, as appropriate to the physical situation, when a bounded solver is used to solve equations 2-5. According to one non-limiting example, an “lsqcurvefit” function in MATLAB® (a MathWorks® product) may be used to solve equations 2-5. As indicated above, the emission intensity values (EI₁₁-E₁₄) at pixel P₁, the T₁ value, and frequency values (F₁-F₄) are known. At 224, an ambient temperature measurement Tₐ for the entire DUT 104 is received. This value may be the temperature at which the DUT substrate is maintained based on cooling.

At 226, the temperature value (T) at pixel P₁ (P_{y} where y=1) location is determined by:

T−Tₐ=c·Fₓ+d Equation 6

The value of T can thus be determined from equation 6 for the different frequency conditions or values (F₁-F₄) applied to the DUT 104. For example, since F₁, d, c, and Tₐ are known, the temperature T of the DUT 104 at pixel location P₁ is determined at an operating clock frequency of F₁. Similarly, since F₂, d, c, and Tₐ are known, the temperature T of the DUT 104 at pixel location P₁ is determined at an operating clock frequency of F₂. Also, for known values of F₃, F₄, d, c, and Tₐ, the temperature values T of the DUT 104 at pixel location P₁ are determined at clock frequencies F₃ and F₄. It may be further appreciated that since d, c, and Tₐ are known, the temperature T can be calculated for any frequency value F (i.e., Fₓ=F), where F is generic. However, as in any fitting, errors in the estimated temperature value T increases as the value of the generic frequency F deviates from the frequency range (i.e., F₁ to F₄) used in the test. It may be further appreciated that T-Tₐ may represent a change in temperature as a function of frequency, as given by ΔT. In some embodiment, ΔT may be determined by cFₓ. Therefore three equations are necessary (i.e., solving for a, b, and c) rather than four equations (i.e., solving for a, b, c, and d). In such an alternative embodiment, d can be discarded in equations 1-5.

At 228, it is determined whether the last pixels associated with the acquired images have been processed, where M is designated as the last pixel in the array of pixels. For example, if each of the acquired images includes an array of ‘1024’ pixels, the last pixel and therefore M would be assigned a value of ‘1024’. In the current example, the value of y was set to ‘1’ (i.e., the first pixel locations to be processed) and, therefore, y=1 is not equal to M=1024. Based on this condition, at 230, the value of y is incremented (i.e., from y=1 to y=2) and the process returns to 218 in order to determine the temperature value (T) at the next pixel P₂ location.

Back at 218, for the next pixel P_{y} (P₂, where y=2) location corresponding to all the acquired DUT images (IMₓ), emission intensity measurements EI_{yx} from the DUT images are received. For example, for pixel P₂ corresponding to acquired image IM₁, emission intensity measurement EI₁₁ is received. For pixel P₂ corresponding to acquired image IM₂, emission intensity measurement EI₁₂ is received. For pixel P₂ corresponding to acquired image IM₃, emission intensity measurement EI₁₃ is received. For pixel P₂ corresponding to acquired image IM₄, emission intensity measurement EI₁₄ is received. Therefore, the emission intensity measurements for the same pixel (P₂) location on all the acquired images (IM₁-IM₄) are received for processing.

At 220, as previously described, N photon emission equations PEₓ (x=1 . . . N) are generated from an Emission Model for the pixel P₂ (P_{y} where y=2) location based on the frequency conditions Fₓ (x=1 . . . N) applied to the DUT and the received emission intensity measurements EI_{yx} from the DUT images (IMₓ). Each equation PEₓ is given by:

EI_{xy}=a·Fₓ+b·e^{[(c·F}^{ₓ}^{+d)]/T}^{_{L}} Equation 1

Four (4) photon emission equations PE₁-PE₄ are now generated for pixel P₂ (i.e., y=2), whereby:

EI₂₁=a·F₁+b·e^{[(c·F}^{₁}^{+d)]/T}^{_{L}} Equation 7

EI₂₂=a·F₂+b·e^{[(c·F}^{₂}^{+d)]/T}^{_{L}} Equation 8

EI₂₃=a·F₃+b·e^{[(c·F}^{₃}^{+d)]/T}^{_{L}} Equation 9

EI₂₄=a·F₄+b·e^{[(c·F}^{₄}^{+d)]/T}^{_{L}} Equation 10

Equations 7-10 above are photon emission equations for a single other pixel position based on the DUT 104 being operated at different clock frequency conditions (F₁-F₄).

At 222, equations 7-10 are solved for determining new values of unknown constants a, b, c, and d. Constants a-d may be bound to be either positive or negative in value, as appropriate to the physical situation, when a bounded solver is used to solve equations 2-5. According to one non-limiting example, an “lsqcurvefit” function in MATLAB® (a MathWorks® product) may be used to solve equations 2-5. As indicated above, the emission intensity values (EI₁₁-E₁₄) at pixel P₂, the T_{L} value, and frequency values (F₁-F₄) are known. At 224, an ambient temperature measurement Tₐ for the entire DUT 104 is received. This value may be the temperature at which the DUT substrate is maintained based on cooling.

At 226, the temperature value (T) at pixel P₂ (P_{y} where y=2) location is determined by:

T−Tₐ=c·Fₓ+d Equation 11

The value of T can thus be determined from equation 11 for the different frequency conditions or values (F₁-F₄) applied to the DUT 104. For example, since F₁, d, c, and Tₐ are known, the temperature T of the DUT 104 at pixel location P₂ is determined at an operating clock frequency of F₁. Similarly, since F₂, d, c, and Tₐ are known, the temperature T of the DUT 104 at pixel location P₂ is determined at an operating clock frequency of F₂. Also, for known values of F₃, F₄, d, c, and Tₐ, the temperature values T of the DUT 104 at pixel location P₂ are determined at clock frequencies F₃ and F₄. It may be further appreciated that since d, c, and Tₐ are known, the temperature T can be calculated for any frequency value F (i.e., Fₓ=F), where F is generic. However, as in any fitting, errors in the estimated temperature value T increases as the value of the generic frequency F deviates from the frequency range (i.e., F₁ to F₄) used in the test. It may be further appreciated that T-Tₐ may represent a change in temperature as a function of frequency, as given by ΔT. In some embodiment, ΔT may be determined by cFₓ. Therefore three equations are necessary (i.e., solving for a, b, and c) rather than four equations (i.e., solving for a, b, c, and d). In such an alternative embodiment, d can be discarded in equations 1-5.

At 228, it is once again determined whether the last pixels associated with the acquired images has been processed, where M is designated as the last pixel in the array of pixels. For an array of ‘1024’ pixels, the last pixel and therefore M would be assigned a value of ‘1024’. In the current example, the value of y was incremented to ‘2’ (i.e., the first pixel locations to be processed) and, therefore, y=2 is still not equal to M=1024. Based on this condition, at 230, the value of y is again incremented (i.e., from y=1 to y=2) and the process returns to 218 in order to determine the temperature value (T) at the next pixel P₃ location.

Processes 218 through 230 iteratively continue until the constants (a, b, c, and d) and temperature values for all pixels (i.e., M pixels) have been determined in the manner described above. For descriptive brevity, two iterations of processes 218 through 230 have been described for pixels P₁ and P₂. However, for M pixels associated with each captured image (IM₁-IM₄) of the DUT 104, M iterations of processes 218 through 230 occur.

Once the constants (a, b, c, and d) and temperature values for all pixels (i.e., M pixels) have been determined, the process advances to FIG. 2C, whereby different exemplary applications can be realized using the determined constants (a, b, c, and d) and temperature values for all the pixels (i.e., M pixels) of the DUT 104.

Referring to FIG. 2C, at 232, temperature maps similar to those illustrated in FIG. 4 may be generated based on the temperature values determined for each pixel location from the DUT images for different operating conditions (e.g., clock frequencies F₁-F₄ driving the DUT). At 234, for example, the cooling applied to the DUT can be controlled via a control signal in order to address certain detected hotspot areas on the DUT from the temperature maps (232).

According to an alternative embodiment, at 234, one or more operating parameters of the DUT may be varied via a control signal to alleviate the created hotspots or any other overheating of components within the DUT. According to one non-limiting example, the supply voltage to the DUT may be appropriately reduced using the operating condition controller 112. According to another example, the clock frequency value may be reduced (e.g., from F₃=2400 MHz to F₂=1200 MHz) using the operating condition controller 112. In this scenario, if the generated temperature map for F₂=1200 MHz still indicates areas of the DUT running at excessive temperatures, the clock frequency value may be further reduced (e.g., to F₁=600 MHz) via the operating condition controller 112.

At 236, an on-chip temperature sensor associated with the DUT can be calibrated using the generated temperature maps. For each temperature sensor output value created by controlling the temperature of the DUT, processes 202-230 (FIGS. 2A-2B) are used to generate a temperature map of the DUT at the operating clock frequency (i.e., Fₓ) applied to the DUT 104. In particular, at process 226 (FIG. 2B), based on the acquired/determined known values of d (determined for each pixel location), c (determined for each pixel location), Fₓ, and Tₐ, temperature values T at each pixel location are used to generate the temperature map. The measured on-chip sensor temperature changes are then correlated with the determined temperatures at the pixel regions on the DUT. For example, referring to FIG. 4, an on-chip temperature sensor 407 indicating an output of 45° C. may be correlated with generated temperature map 400A. Thus, at pixel location 406A, the corresponding generated temperature map 400A illustrates a determined temperature value of 41° C., as indicated at 408A. Similarly, for the on-chip temperature sensor output of 45° C., at pixel location 410A, the corresponding generated temperature map 400A illustrates a determined temperature value of 43° C., as indicated at 412A. According to another example, for the on-chip temperature sensor output of 45° C., at pixel location 414A, the corresponding generated temperature map 400A illustrates a determined temperature value of 71° C., as indicated at 416A. For illustrative brevity only four temperature values are shown on temperature map 400A. However, it will be appreciated that the temperature map contemplates a determined temperature value for each of the corresponding pixel locations 404A associated with the DUT based on a temperature sensor output of 45° C.

For example, the on-chip temperature sensor 407 indicating an alternative output of 65° C. may be correlated with another generated temperature map 400B. Thus, at pixel location 406B, the corresponding generated temperature map 400B illustrates a determined temperature value of 51° C., as indicated at 408B. Similarly, for the on-chip temperature sensor output of 65° C., at pixel location 410B, the corresponding generated temperature map 400B illustrates a determined temperature value of 57° C., as indicated at 412B. According to another example, for the on-chip temperature sensor output of 65° C., at pixel location 414B, the corresponding generated temperature map 400B illustrates a determined temperature value of 91° C., as indicated at 416B. For illustrative brevity only four temperature values are shown on temperature map 400B. However, it will be appreciated that the temperature map contemplates a determined temperature value for each of the corresponding pixel locations 404B associated with the DUT based on a temperature sensor output of 65° C.

Further, although the foregoing example describes two correlated on-chip temperature sensor output values, it will be appreciated that many on-chip temperature sensor output values and corresponding temperature maps can be generated. Thus, using such an embodiment, by knowing an on-chip temperature sensor output value, temperature values at precise locations of the chip are known. This enables real-time monitoring of the operation of critical parts of the chip, in particular, locations where excessive component level temperatures can cause catastrophic chip failures.

At 238, DUT process variation analysis can be carried out based on the non-linear leakage emission component of the photon emission equation EI_{yx} at the location of a given pixel or pixels. In particular, at process 220 (FIG. 2B), the non-linear component of the photon emission equation EI_{yx} is given by:

b·e^{[(c·F}^{ₓ}^{+d)]/T}^{_{L}} Equation 12

Thus, at each pixel location, using the calculated b, c, d values, and the know T_{L} and Fₓ values, the contribution of leakage emission to the emission intensity EI_{yx} at each pixel location can be determined. It may be further appreciated that since b, c, d, and T_{L} are known, the contribution of leakage emission to the emission intensity EI_{yx} can be calculated for any frequency value F (i.e., Fₓ=F), where F is generic. However, as in any fitting, errors in the estimated contribution of leakage emission to the emission intensity EI_{yx} increases as the value of the generic frequency F deviates from the frequency range (i.e., F₁ to F₄) used in the test. By making these determinations for a number of identical DUTs, changes in leakage current for the same location on identical devices can be assessed in order to, for example, analyze differences in the manufacturing process for individual chips on the same wafer, or between the same chips on different wafers. Using the leakage emission differences at specific locations on each chip, an IC fabrication process control component 114 (FIG. 1) can modify manufacturing parameters (e.g., time, temperature, doping, etc.) in order to reduce leakage emissions between DUTs. Alternatively, if the leakage emission value at one or more locations on one or more of the DUTs exceeds a given threshold, the IC fabrication process control component 114 (FIG. 1) can modify manufacturing parameters in order to try and reduce leakage emission for all DUTs being manufactured.

At 240, the location of active devices operating on the DUT can be determined based on the linear switching emission component of the photon emission equation EI_{yx} at the location of a given pixel or pixels. In particular, at process 220 (FIG. 2B), the linear component of the photon emission equation EI_{yx} is given by:

a·Fₓ Equation 13

Thus, at each pixel location, using the calculated a value, and the know Fₓ value, the contribution of device switching (e.g., transistor or logic gate switching) to the emission intensity EI_{yx} at each pixel location can be determined. It may be further appreciated that since a is known, the contribution of device switching to the emission intensity EI_{yx} can be calculated for any frequency value F (i.e., Fₓ=F), where F is generic. However, as in any fitting, errors in the estimated contribution of device switching to the emission intensity EI_{yx} increases as the value of the generic frequency F deviates from the frequency range (i.e., F₁ to F₄) used in the test. By making these determinations, the location of the active devices on the DUT are known. For example, if a certain area of the DUT generates a larger amount of switching emissions, additional security measures may be incorporated into the packaging of the DUT to reduce emissions from the DUT.

In accordance with the disclosed embodiments, the emission intensity from a given position on a DUT includes two major components: a switching emission and a leakage emission. Furthermore, the first component (i.e., the switching emission) has a linear dependency from the applied chip frequency, while the second component (i.e., the leakage emission) has a non-linear dependency (e.g. exponential dependency) from the applied chip frequency. The choice of applied chip frequencies should be sufficient to detect these different emission characteristics. The wider the applied frequency range (e.g., F₁ to Fₓ range), the more precise the estimated model parameters (i.e., a, b, c, and d) will be. In particular, a frequency range that produces, for example, at least a 10C change in chip temperature is desirable. Moreover, the above-described process for determining the temperature values of the DUT provides for a negligible voltage drop or voltage difference across the DUT based on measurements taken at different applied frequency conditions. Thus, a relatively constant voltage across the DUT may be achieved by, for example, using on-chip voltage sensors to monitor and regulate the voltage to be as constant as possible.

FIG. 3 shows a block diagram of the components of a data processing system 800, 900, that may be incorporated within a processing component 108 (FIG. 1) in accordance with an illustrative embodiment of the present invention. It should be appreciated that FIG. 3 provides only an illustration of one implementation and does not imply any limitations with regard to the environments in which different embodiments may be implemented. Many modifications to the depicted environments may be made based on design and implementation requirements.

Data processing system 800, 900 is representative of any electronic device capable of executing machine-readable program instructions. Data processing system 800, 900 may be representative of a smart phone, a computer system, PDA, or other electronic devices. Examples of computing systems, environments, and/or configurations that may represented by data processing system 800, 900 include, but are not limited to, personal computer systems, server computer systems, thin clients, thick clients, hand-held or laptop devices, multiprocessor systems, microprocessor-based systems, network PCs, minicomputer systems, and distributed cloud computing environments that include any of the above systems or devices.

The data processing system 800, 900 may include may include a set of internal components 800 and a set of external components 900 illustrated in FIG. 3. The set of internal components 800 includes one or more processors 820, one or more computer-readable RAMs 822 and one or more computer-readable ROMs 824 on one or more buses 826, and one or more operating systems 828 and one or more computer-readable tangible storage devices 830. The one or more operating systems 828 and programs such as photon-based temperature determination (PTD) Program 124 (also see FIG. 1) is stored on one or more computer-readable tangible storage devices 830 for execution by one or more processors 820 via one or more RAMs 822 (which typically include cache memory). In the embodiment illustrated in FIG. 3, each of the computer-readable tangible storage devices 830 is a magnetic disk storage device of an internal hard drive. Alternatively, each of the computer-readable tangible storage devices 830 is a semiconductor storage device such as ROM 824, EPROM, flash memory or any other computer-readable tangible storage device that can store a computer program and digital information.

The set of internal components 800 also includes a R/W drive or interface 832 to read from and write to one or more portable computer-readable tangible storage devices 936 such as a CD-ROM, DVD, memory stick, magnetic tape, magnetic disk, optical disk or semiconductor storage device. The PTD program 124 can be stored on one or more of the respective portable computer-readable tangible storage devices 936, read via the respective R/W drive or interface 832 and loaded into the respective hard drive 830.

The set of internal components 800 may also include network adapters (or switch port cards) or interfaces 836 such as a TCP/IP adapter cards, wireless wi-fi interface cards, or 3G or 4G wireless interface cards or other wired or wireless communication links. PTD program 124 can be downloaded from an external computer (e.g., server) via a network (for example, the Internet, a local area network or other, wide area network) and respective network adapters or interfaces 836. From the network adapters (or switch port adaptors) or interfaces 836, the PTD program 124 is loaded into the respective hard drive 830. The network may comprise copper wires, optical fibers, wireless transmission, routers, firewalls, switches, gateway computers and/or edge servers.

The set of external components 900 can include a computer display monitor 920, a keyboard 930, and a computer mouse 934. External component 900 can also include touch screens, virtual keyboards, touch pads, pointing devices, and other human interface devices. The set of internal components 800 also includes device drivers 840 to interface to computer display monitor 920, keyboard 930 and computer mouse 934. The device drivers 840, R/W drive or interface 832 and network adapter or interface 836 comprise hardware and software (stored in storage device 830 and/or ROM 824).

As described in the foregoing, the process of FIGS. 2A-2C may be executed on any suitable computer processing platform or architecture. As depicted in FIG. 1, the process of FIGS. 2A-2C (i.e., PTD program) is executed on component 108. Accordingly, component 108 can reside either within the microscope apparatus 102, reside as a standalone computer device outside the microscope apparatus 102, or be implemented as a cloud-based service over a communication network.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A computer-implemented method comprising:
receiving a plurality of images from a device under test (DUT), wherein each of the plurality of images is generated by operating the DUT at a different frequency condition;
receiving emission intensity values from a corresponding pixel location on each of the received plurality of images;
receiving, for the DUT, an electrical leakage current parameter corresponding to a change in leakage current based on a change in temperature;
receiving, for the DUT, a temperature parameter corresponding to an ambient temperature value at which the DUT is maintained; and
determining a temperature value at the corresponding pixel location based on the different frequency conditions, the emission intensity values associated with the different frequency conditions, and the electrical leakage current parameter, and the ambient temperature value.

2. The computer-implemented method of claim 1, wherein the temperature value at the corresponding pixel location is used to control at least one operating condition of the DUT.

3. The computer-implemented method of claim 1, wherein the temperature value at the corresponding pixel location calibrates an on-chip temperature sensor on the DUT by correlating an output temperature from the on-chip temperature sensor to the temperature value at the corresponding pixel location.

4. The computer-implemented method of claim 1, wherein the emission intensity values from the corresponding pixel location on each of the plurality of images are determined by electrical current variations at the corresponding pixel location, as measured using an image sensor device, the emission intensity values being proportional to electrical current and photon count values from the corresponding pixel location on each of the plurality of images.

5. The computer-implemented method of claim 4, wherein the image sensor device comprises a static camera device attached to a microscope for receiving images from the microscope.

6. The computer-implemented method of claim 4, wherein the image sensor device is selected from the group consisting of an Indium Gallium Arsenide (InGaAs) camera, a charge coupled device (CCD), and a Mercury Cadmium Telluride (MCT) Camera.

7. The computer-implemented method of claim 1, further comprising:
receiving other emission intensity values from other corresponding pixel locations on each of the received plurality of images; and
determining other temperature values at the other corresponding pixel locations based on the different frequency conditions, the other emission intensity values associated with the different frequency conditions, the electrical leakage current parameter, and the ambient temperature value.

8. The computer-implemented method of claim 7, wherein the other temperature values at the other corresponding pixel locations control at least one process associated with an operating condition of the DUT.

9. The computer-implemented method of claim 7, wherein the other temperature values at the other corresponding pixel locations calibrate an on-chip temperature sensor on the DUT by correlating an output temperature from the on-chip temperature sensor to the temperature value at the corresponding pixel location.

10. The computer-implemented method of claim 1, wherein the different frequency conditions comprise at least four different frequency values and the plurality of images comprise at least four images from the device under test (DUT) for the determining of the temperature value at the corresponding pixel location.

11. The method of claim 1, wherein the determining of the temperature value at the corresponding pixel location comprises:
for x=1 to 4, solving a relationship given by:
$${EI}_{x} = a \cdot {F}_{x} + b \cdot exp ( [ \frac{( c \cdot {F}_{x} + d )}{{T}_{L}} ] ) ,$$
where EIₓ is the emission intensity values at the corresponding pixel location for each of the different frequency conditions Fₓ, T_{L} is the electrical leakage current parameter, and a, b, c, and d are constants to be determined by the solved relationship; and
responsive to determining constants a, b, c, and d, determining the temperature value T based on the relationship given by:
T−Tₐ=c·Fₓ+d, where Tₐ is the ambient temperature value at which the DUT is maintained.

12. A computer program product comprising:
one or more non-transitory computer-readable storage devices and program instructions stored on at least one of the one or more non-transitory storage devices, the program instructions executable by a processor, the program instructions comprising:
instructions to receive a plurality of images from a device under test (DUT), wherein each of the plurality of images is generated by operating the DUT at a different frequency condition;
instructions to receive emission intensity values from a corresponding pixel location on each of the received plurality of images;
instructions to receive, for the DUT, an electrical leakage current parameter corresponding to a change in leakage current based on a change in temperature;
instructions to receive, for the DUT, a temperature parameter corresponding to an ambient temperature value at which the DUT is maintained; and
instructions to determine a temperature value at the corresponding pixel location based on the different frequency conditions, the emission intensity values associated with the different frequency conditions, the electrical leakage current parameter, and the ambient temperature value.

13. The computer program product of claim 12, wherein the temperature value at the corresponding pixel location is used to control at least one process associated with an operating condition of the DUT.

14. The computer program product of claim 12, wherein the temperature value at the corresponding pixel location calibrates an on-chip temperature sensor on the DUT by correlating an output temperature from the on-chip temperature sensor to the temperature value at the corresponding pixel location.

15. The computer program product of claim 12, further comprising:
instructions to receive other emission intensity values from other corresponding pixel locations on each of the received plurality of images; and
instructions to determine other temperature values at the other corresponding pixel locations based on the different frequency conditions, the other emission intensity values associated with the different frequency conditions, the electrical leakage current parameter, and the ambient temperature value.

16. The computer program product of claim 15, wherein the other temperature values at the other corresponding pixel locations control at least one process associated with an operating condition of the DUT.

17. The computer program product of claim 15, wherein the other temperature values at the other corresponding pixel locations calibrate the on-chip temperature sensor on the DUT by correlating other output temperatures from the on-chip temperature sensor to the other temperature values at the other corresponding pixel locations.

18. The computer program product of claim 12, wherein the instructions to determine the temperature value at the corresponding pixel location comprises:
for x=1 to 4, solving a relationship given by:
$${EI}_{x} = a \cdot {F}_{x} + b \cdot exp ( [ \frac{( c \cdot {F}_{x} + d )}{{T}_{L}} ] ) ,$$
where EIₓ is the emission intensity values at the corresponding pixel location for each of the different frequency conditions Fₓ, T_{L} is the electrical leakage current parameter, and a, b, c, and d are constants to determined by the solved relationship; and
responsive to determining constants a, b, c, and d, determining the temperature value T based on the relationship given by:
T−Tₐ=c·Fₓ+d, where Tₐ is the ambient temperature value at which the DUT is maintained.

19. A computer system comprising:
one or more processors, one or more computer-readable memories, one or more non-transitory computer-readable storage devices, and program instructions stored on at least one of the one or more non-transitory storage devices for execution by at least one of the one or more processors via at least one of the one or more memories, wherein the computer system is capable of performing a method comprising:
receiving a plurality of images from a device under test (DUT), wherein each of the plurality of images is generated by operating the DUT at a different frequency condition;
receiving emission intensity values from a corresponding pixel location on each of the received plurality of images;
receiving, for the DUT, an electrical leakage current parameter corresponding to a change in leakage current based on a change in temperature;
receiving, for the DUT, a temperature parameter corresponding to an ambient temperature value at which the DUT is maintained; and
determining a temperature value at the corresponding pixel location based on the different frequency conditions, the emission intensity values associated with the different frequency conditions, the electrical leakage current parameter, and the ambient temperature value.

20. The system of claim 19, wherein the temperature value at the corresponding pixel location is used to control at least one process associated with an operating condition of the DUT.

21. A computer-implemented method comprising:
receiving a plurality of images from a device under test (DUT), wherein each of the plurality of images is generated by operating the DUT at a different frequency condition;
receiving emission intensity values from a corresponding pixel location on each of the received plurality of images;
receiving, for the DUT, an electrical leakage current parameter corresponding to a change in leakage current based on a change in temperature; and
determining a temperature value at the corresponding pixel location based on the different frequency conditions, the emission intensity values associated with the different frequency conditions, and the electrical leakage current parameter.

22. The computer-implemented method of claim 1, wherein the temperature value includes a temperature change value (ΔT) at the corresponding pixel location.

23. The computer-implemented method of claim 1, further comprising:
receiving, for the DUT, a temperature parameter corresponding to an ambient temperature value at which the DUT is maintained, the temperature parameter used to determine the temperature value at the corresponding pixel location, wherein the temperature value includes an actual temperature (T).

24. The computer-implemented method of claim 21, wherein the temperature value at the corresponding pixel location is used to control at least one operating condition of the DUT.

25. The computer-implemented method of claim 21, wherein the temperature value at the corresponding pixel location calibrates an on-chip temperature sensor on the DUT by correlating an output temperature from the on-chip temperature sensor to the temperature value at the corresponding pixel location.
